(19) United States
(12) Patent Application Publication
(10) Pub. No.: US 2020/0110491 A1
(43) Pub. Date: Apr. 9, 2020

(54) METHOD FOR MANUFACTURING A PATTERNED SILVER NANOWIRE FILM, A TOUCH SCREEN AND A MANUFACTURING METHOD THEREOF

(71) Applicant: Kunshan Go-Visionox Opto-Electronics Co., Ltd., Kunshan (CN)

(72) Inventor: Yuhao LAI, KunShan (CN)

(21) Appl. No.: 16/706,871

(22) Filed: Dec. 9, 2019

Related U.S. Application Data
(63) Continuation of application No. PCT/CN2019/071228, filed on Jan. 10, 2019.

(30) Foreign Application Priority Data
Jun. 30, 2018 (CN) 201810703170.4

(51) Int. Cl. G06F 3/047; H05K 3/12; H01B 1/02

(52) U.S. Cl. CPC G06F 3/047; H05K 3/1283; G06F 2203/04103; H01B 1/02; H05K 2203/0783; H05K 3/1216

(57) ABSTRACT

The present application provides a method for manufacturing a patterned silver nanowire film, a touch screen and a manufacturing method thereof. The method for manufacturing a patterned silver nanowire film, includes: forming a patterned surface modification layer on a substrate; coating a silver nanowire solution on the substrate, the surface modification layer repels the silver nanowire solution, the silver nanowire solution is automatically scattered on the surface modification layer and is gathered onto a portion of the substrate that is not covered by the surface modification layer; and performing a baking process to cure the silver nanowire solution to form the patterned silver nanowire film.

### CROSS-REFERENCES TO RELATED APPLICATIONS

The present application is a continuation application to PCT Application No. PCT/CN2019/071228, filed Jan. 10, 2019, which claims priority to Chinese Patent Application No. 201810703170.4, filed Jun. 30, 2018. Both applications are incorporated by reference herein for all purposes.

### TECHNICAL FIELD

The present application relates to the field of preparation of transparent conductive films, and particularly relates to a method for manufacturing a patterned silver nanowire film, a touch screen and a manufacturing method thereof.

### BACKGROUND

Silver nanowire material is a popular material in transparent conductive film in recent years. It has very high conductivity and transparency, and excellent flexibility, and has a very good application prospect in the field of flexible touch screen. At present, the manufacturing method of a silver nanowire film is carried out, for example, by directly coating a silver nanowire solution onto a substrate, and then patterning the silver nanowire film by laser etching (also referred to as laser ablation) technique. The laser etching technique is a method of rapidly heating, melting or vaporizing the surface of a material to be etched by using short-pulse-width, high-peak-power laser pulses to achieve precise removal of the surface material. Laser etching technology requires the use of a high-precision laser processing equipment to etch patterns step by step.

### SUMMARY

An object of the present application is to provide a method for manufacturing a patterned silver nanowire film, a touch screen and a manufacturing method thereof in order to solve the problems of high cost, low efficiency, and waste of materials in the method for manufacturing a patterned silver nanowire film.

In this regard, the embodiments of the present application provide a method for manufacturing a patterned silver nanowire film, includes: forming a patterned surface modification layer on a substrate; coating a silver nanowire solution onto the substrate, wherein the surface modification layer repels the silver nanowire solution, so that the silver nanowire solution is automatically scattered on the surface modification layer and is gathered onto a portion of the substrate that is not covered by the surface modification layer; and performing a baking process to cure the silver nanowire solution to form the patterned silver nanowire film.

Optionally, the surface modification layer has hydrophobicity when the silver nanowire solution has an aqueous solvent.

Optionally, the surface modification layer is formed by a surface modifier, and the surface modifier includes one or more of a silane coupling agent, a linear alkyl type surface modifier, a branched alkyl type surface modifier, a rosin derivative surface modifier, a fluoroalkyl surface modifier, a polysiloxane based surface modifier.

Optionally, the surface modification layer has a first pattern, and the silver nanowire film has a second pattern, the first pattern and the second pattern are complementary and collectively cover the entire substrate.

Optionally, the surface modification layer is formed by the following steps: providing a transfer plate; coating a patterned surface modifier onto the transfer plate; transferring the surface modifier from the transfer plate to the substrate by a transfer printing method; and curing the surface modifier to form the surface modification layer.

Optionally, the surface modifier in the first pattern is formed on the transfer plate by a screen printing method.

Optionally, the silver nanowire solution comprises a plurality of sliver nanowires which are distributed in a solvent of the silver nanowire solution.

Optionally, the silver nanowire solution has a concentration of 0.01 mg/mL to 10 mg/mL.

Optionally, the solvent of the silver nanowire solution is ethylene glycol or isopropanol.

Furthermore, the embodiments of the present application also provide a method for manufacturing a touch screen, wherein, the touch screen comprises a patterned silver nanowire film which is manufactured by the aforementioned method for manufacturing a patterned silver nanowire film.

Correspondingly, the embodiments of the present application also provide a touch screen, comprising: a substrate; a patterned surface modification layer formed on the substrate; and a patterned silver nanowire film formed on a portion of the substrate that is not covered by the surface modification layer.

Optionally, the surface modification layer has a first pattern, and the silver nanowire film has a second pattern, the first pattern and the second pattern are complementary and collectively cover the entire substrate.

Optionally, the patterned silver nanowire film is manufactured by the aforementioned method for manufacturing a patterned silver nanowire film. Since laser etching technique is not used in the manufacturing method in the embodiments of the present application, no sintering trace caused by laser etching is produced on the substrate of the touch screen, so that the touch screen has better performance and quality.

The present application provides a method for manufacturing a patterned silver nanowire film and a touch screen, by firstly forming a patterned surface modification layer on a substrate, and then coating a silver nanowire solution onto the substrate, wherein, by utilizing the property that the surface modification layer repels the silver nanowire solution, the silver nanowire solution can be automatically scattered on the surface modification layer and is gathered onto a portion of the substrate that is not covered by the surface modification layer, thereby forming a patterned silver nanowire film after the silver nanowire solution is cured.

Therefore, unlike the existing laser etching technology, the method for manufacturing the patterned silver nanowire film provided by the present application has a simple and rapid process, can be applied to large-scale production, and can reduce equipment cost. In addition, there is no waste of the silver nanowire solution in the production process, which improves the utilization rate of the silver nanowire material. Therefore, the present application provides a low-cost and high-efficiency method for manufacturing a patterned silver nanowire film. Moreover, since laser etching technique is avoided in this method, there is no laser etching sintering trace produced on the touch screen manufactured with the silver nanowire film, so that the touch screen manufactured by this method has better performance and quality.

### BRIEF DESCRIPTION OF THE DRAWINGS

FIG. 1 shows a schematic flow diagram of a method for manufacturing a patterned silver nanowire film according to an embodiment of the present application;

FIGS. 2 and 3 show schematic top views of a patterned silver nanowire film in a forming process thereof according to an embodiment of the present application;

FIG. 4 shows a schematic flow diagram of a method for forming a surface modification layer in an embodiment of the present application.

### DETAILED DESCRIPTION OF THE INVENTION

The existing laser processing equipment has a relatively low processing efficiency.

Therefore, in order to meet the demand of high yield, more laser processing equipment is needed. However, expensive cost of the laser processing equipment results in an increase in the cost of the invested equipment. In addition, laser etching will ablate some of the sliver nanowires, which will cause a considerable amount of waste of sliver nanowire material after long-term accumulation, leading to an increase in material costs.

Hereinafter, a method for manufacturing a patterned silver nanowire film proposed by the present application will be further described in detail with reference to the accompanying drawings and specific embodiments. Advantages and features of the present application will become more apparent from the description as follows. It should be noted that the drawings are in a very simplified form and all use non-precise proportions, and are only used for the purpose of easily and clearly explaining the embodiments of the present application.

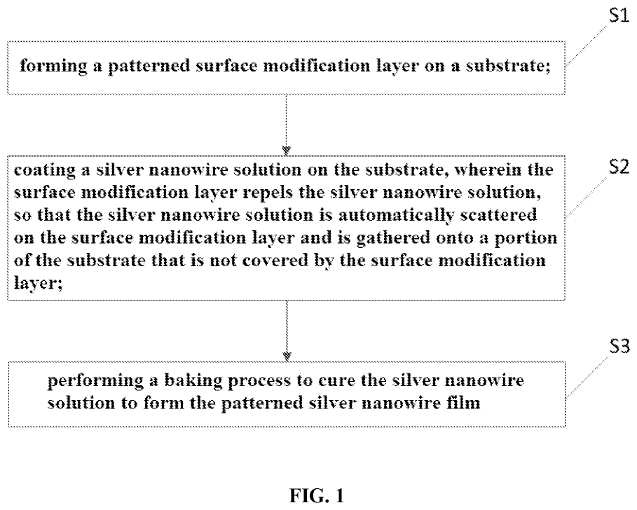

In the present embodiment, a method for manufacturing a patterned silver nanowire film is provided, as shown in FIGS. 1-3, the method is specifically divided into the following steps:

Firstly, performing step S1 to form a patterned surface modification layer 2 on a substrate 1.

Specifically, the substrate 1 may be, for example, a glass substrate, or may be a flexible substrate formed by a flexible material which may be polyimide material, PET plastic, etc. Since the present embodiment pays more attention to the method for manufacturing the silver nanowire film, it is only required that silver nanowires can be formed on the substrate 1, and there is no excessive requirement on the materials of the substrate 1. Therefore, a person skilled in the art can choose appropriate substrate materials as needed.

In the present embodiment, a patterned surface modification layer 2 is formed on the substrate 1, which can change the surface characteristics of the substrate 1, so that the area with the patterned surface modification layer 2 formed on the substrate 1 has a surface characteristic different from that of the substrate 1. Therefore, when the silver nanowire solution is subsequently coated, the silver nanowire solution is automatically scattered on the surface modification layer 2 and is gathered onto a portion of the substrate 1 that is not covered by the surface modification layer 2, due to the repulsive action of the surface modification layer 2.

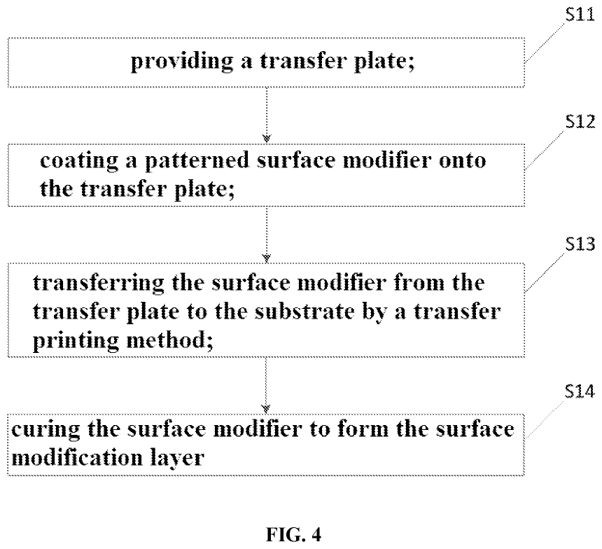

As a preferred embodiment, FIG. 4 is a schematic flow diagram showing a method for forming the surface modification layer in an embodiment of the present application. Referring to FIG. 4, the surface modification layer is formed by the following steps:

S11: providing a transfer plate;

S12: coating a patterned surface modifier onto the transfer plate;

S13: transferring the surface modifier from the transfer plate to the substrate 1 by a transfer printing method; and

S14: curing the surface modifier to form the surface modification layer.

Specifically, in the present embodiment, a patterned surface modifier is transferred to the substrate 1 by a transfer printing method. Firstly, performing step S11 to prepare a transfer plate which will be used as a carrier for transferring the surface modifier. Next, performing step S12 by coating a patterned surface modifier onto the transfer plate. Then, performing step S13 to transfer the surface modifier from the transfer plate to the substrate 1 by a transfer printing method. Finally, performing step S14 to carry out a baking process on the substrate 1 printed with the patterned surface modifier to achieve the curing of the surface modifier, thereby forming the surface modification layer 2. Alternatively, other processes can be performed in the step S14 as long as the process is capable of curing the surface modifier.

As an optional technical solution, the surface modifier in a first pattern is formed on the transfer plate by a screen printing method.

Specifically, with respect to the above-described step S12, as a method for forming the patterned surface modifier, a screen printing method is proposed in the present embodiment, that is, printing a patterned surface modifier by screen printing onto the transfer plate, during the screen printing process, printing of the surface modifier in a predetermined pattern is achieved by using a pre-made screen mask plate. In the present embodiment, the pattern presented by the patterned surface modifier is referred to as a first pattern. Therefore, in the present embodiment, a patterned surface modifier formed on the transfer plate is realized by a screen printing method.

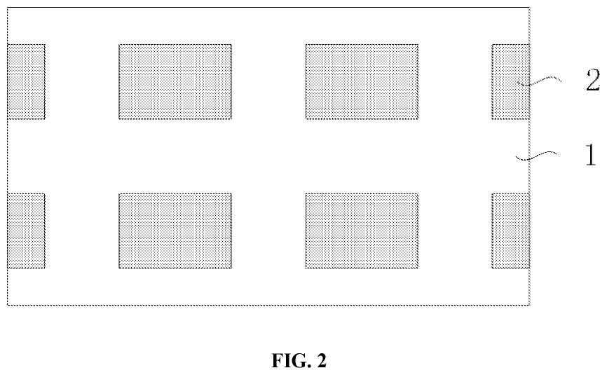

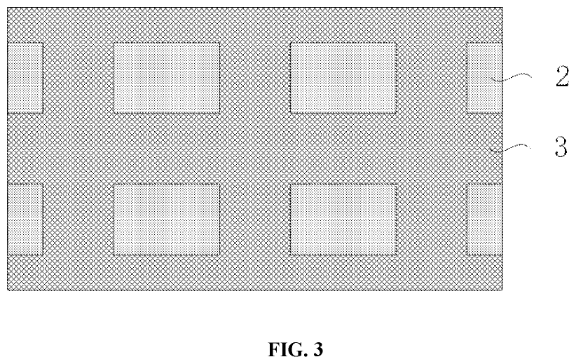

Next, step S2 is performed to coat a silver nanowire solution onto the substrate 1, referring to FIGS. 2 and 3, the surface modification layer 2 repels the silver nanowire solution, so that the silver nanowire solution is automatically scattered on the surface modification layer 2 and is gathered onto a portion of the substrate 1 that is not covered by the surface modification layer 2.

Specifically, for the portion of the substrate 1 that is not covered by the surface modification layer 2, that is, for the exposed portion of the substrate 1, since the silver nanowire solution does not repel the substrate 1, when the silver nanowire solution is coated onto the substrate 1, the silver nanowire solution naturally spreads out due to its own weight, thereby wetting the exposed portion of the substrate 1.

In contrast, for the portion of the substrate 1 where the surface modification layer 2 is formed, that is, for the surface modification layer 2, since the material of the surface modification layer 2 used in the present embodiment repels the silver nanowire solution, so when the silver nanowire solution is coated onto the surface modification layer 2, the silver nanowire solution will not naturally spread out and wet the surface modification layer 2. At the same time, there is a small adsorption force between the silver nanowire solution and the surface modification layer 2, so it is extremely easy for the silver nanowire solution to move on the surface modification layer 2. Furthermore, since the portion of the silver nanowire solution coated on the surface modification layer 2 and the portion of the silver nanowire solution coated on the exposed portion of the substrate 1 are interconnected to each other, the portion of the silver nanowire solution coated on the surface modification layer 2 will be driven and guided under the action of the liquid surface tension, and will automatically scatter on the surface modification layer 2 and gradually gather onto the exposed portion of the substrate 1. Furthermore, in the above process of the present embodiment, the properties of the surface modification layer 2 are fully utilized so that the silver nanowire solution is automatically gathered onto the exposed portion of the substrate 1, thereby realizing the patterning of the silver nanowire solution.

In addition, as compared with the existing laser etching technique, in the present embodiment, a surface modification layer 2 is used to guide the silver nanowire solution to scatter to the exposed portion of the substrate 1, so as to achieve the patterning of the silver nanowire film. Therefore, there is no waste of silver nanowire material in the method of the present embodiment, so the utilization rate of silver nanowire material is increased. Furthermore, since laser etching technique is not used, there is no laser etching sintering trace produced on the surface of the substrate 1.

Furthermore, the silver nanowire solution comprises a plurality of sliver nanowires which are distributed in a solvent. The silver nanowire solution has a concentration of 0.01 mg/mL to 10 mg/mL, for example, 0.05 mg/mL, 0.1 mg/mL, 0.5 mg/mL, 1 mg/mL, 2 mg/mL, 3 mg/mL, 4 mg/mL, 5 mg/mL, 6 mg/mL, 7 mg/mL, 8 mg/mL, 9 mg/mL, etc. A person skilled in the art can flexibly select the concentration of the silver nanowire solution according to actual process capability and product requirements.

As a preferred technical solution, the surface modification layer 2 has hydrophobicity when the silver nanowire solution has an aqueous solvent.

Specifically, one solvent commonly used in the silver nanowire solution currently is water, and other solvents are such as ethylene glycol and isopropanol. In this embodiment, a method for manufacturing a patterned silver nanowire film is provided when the silver nanowire solution uses water as a solvent. The surface modification layer 2 is manufactured with a material that repels water, so it has hydrophobicity. The reason why the silver nanowire solution having water as a solvent in the present embodiment repels the surface modification layer 2 having hydrophobicity is because water is a polar substance which can form hydrogen bonds inside, while the solute molecules in the surface modifier used in preparing the surface modification layer 2 tend to be non-polar, which makes these molecules unable to form hydrogen bonds and thus insoluble with water, thereby causing mutual repulsion.

In addition, the hydrophobicity of the surface modification layer 2 in this embodiment is also manifested in that a large contact angle will form and a droplet shape will be presented, instead of automatically spreading out, when water droplets contact the surface of a hydrophobic material. The contact angle refers to an intersection angle formed at the liquid side between the solid-liquid boundary line and the tangent line of the gas-liquid interface at the intersection point of gas, liquid and solid three phases. The contact angle is a measurement of the wettability of liquid to solid. When water droplets contact a hydrophilic material, the contact angle formed is small (less than 90°), so that water droplets tend to spread over the surface of the hydrophilic material, thereby wetting the surface of the hydrophilic material. In contrast, when water droplets contact a hydrophobic material, the contact angle formed is large (greater than 90°), thereby forming a droplet-like or even spherical structure. Due to the small adsorption between water droplets and the surface of hydrophobic material, the surface of hydrophobic material is hardly wetted, so it is easy for water droplets to move on the surface of hydrophobic material.

Therefore, in the present embodiment, it is very easy for the silver nanowire solution having water as a solvent to gather to the portion of the substrate 1 that is not covered by the surface modification layer 2 under the action of the hydrophobic surface modification layer 2 and the surface tension of the liquid.

This embodiment does not limit that the solvent of the silver nanowire solution can only be water and the material of the surface modifier can only be a hydrophobic material, but only gives a representative, schematic example and description. For other possible solvents of the silver nanowire solution, such as ethylene glycol, isopropanol, etc., it is also possible to find a surface modifier corresponding to the solvent to produce repulsion, and the effect in the present embodiment can also be achieved. Therefore, a person skilled in the art can make tries according to different solvents of the silver nanowire solution, so as to select a suitable surface modifier.

As an alternative technical solution, the surface modification layer 2 is formed by a surface modifier, and the surface modifier includes one or more of a silane coupling agent, a linear alkyl type surface modifier, a branched alkyl type surface modifier, a rosin derivative surface modifier, a fluoroalkyl surface modifier, a polysiloxane based surface modifier.

In the present embodiment, a plurality of hydrophobic surface modifiers are proposed for the above-mentioned hydrophobic surface modifying layer 2, including one or more of a silane coupling agent, a linear alkyl type surface modifier, a branched alkyl type surface modifier, a rosin derivative surface modifier, a fluoroalkyl surface modifier, a polysiloxane based surface modifier. A person skilled in the art can select a suitable surface modifier according to specific needs.

Finally, step S3 is performed, referring to FIG. 3, a baking process is performed to cure the silver nanowire solution to form a patterned silver nanowire film 3.

Specifically, after the silver nanowire solution gathers onto the exposed portion of the substrate 1, a baking process is performed on the silver nanowire solution to evaporate the solvent in the silver nanowire solution, so that the silver nanowires therein remain and lap-joint to form a silver nanowire film 3. The conditions of the baking process (for example, the baking temperature and the baking time) can be determined by a person skilled in the art according to the specific parameters of the silver nanowire solution, and thus will not be described redundantly herein. Moreover, since the silver nanowire solution positionally avoids the surface modification layer 2, the silver nanowire film 3 also has a corresponding pattern according to the pattern of the surface modification layer 2, thereby realizing the manufacturing of the patterned nanowire thin film 3.

As a preferred technical solution, as shown in FIG. 3, the surface modification layer 2 has a first pattern, and the silver nanowire film 3 has a second pattern, the first pattern and the second pattern are complementary and collectively cover the entire substrate 1.

Specifically, the surface modification layer 2 employed in the present embodiment causes the silver nanowire solution to automatically avoid the portion of the substrate 1 on which the surface modification layer 2 is formed, and become formed on the exposed portion of the substrate 1. Based on this, in the present embodiment, the pattern of the silver nanowire film 3 subsequently formed on the exposed portion of the substrate 1 is determined by pre-setting the pattern of the surface modification layer 2 in advance. Wherein, in the above-described formation step S12 of the surface modification layer 2, the pattern of the surface modification layer 2 has been printed as a first pattern of the surface modifier on the transfer plate by, for example, a screen printing method, then the surface modifier in the first pattern is transferred onto the substrate 1 by a transfer printing method in a subsequent step, which is then cured to form the surface modification layer 2, and the surface modification layer 2 thus obtained is correspondingly presented as the first pattern.

Furthermore, after coating the silver nanowire solution onto the substrate 1, the silver nanowire solution coated on the substrate 1 automatically avoid all the patterned surface modification layer 2 and gather onto the exposed portion of the substrate 1 due to the action of the surface modification layer 2 and the surface tension of the liquid. Therefore, after baking and curing, the solvent in the silver nanowire solution is evaporated, and a patterned silver nanowire film 3 is formed on the substrate 1. In the present embodiment, the pattern presented by the silver nanowire film 3 is referred to as a second pattern. Optionally, the first pattern and the second pattern do not overlap, and the first pattern and the second pattern are complementary and collectively cover the entire substrate 1. That is, the surface modification layer 2 has no overlapping portion with the silver nanowire film 3, and the surface modification layer 2 and the silver nanowire film 3 collectively cover the entire substrate 1.

Moreover, in the present embodiment, a method for manufacturing a touch screen is provided, and the touch screen comprises a patterned silver nanowire film which is manufactured by the method for manufacturing a patterned silver nanowire film as described above. Correspondingly, the present embodiment also provides a touch screen, comprising a substrate 1; a patterned surface modification layer 2 formed on the substrate 1; and a patterned silver nanowire film 3 formed on a portion of the substrate 1 that is not covered by the surface modification layer 2.

As an optional method, the silver nanowire film 3 is manufactured by the method for manufacturing the patterned silver nanowire film as described above. Since laser etching technique is not used in the manufacturing method of the embodiments of the present application, no sintering trace caused by laser etching is produced on the substrate of the touch screen, so that the touch screen manufactured by this method has better performance and quality.

In addition, in this embodiment, a touch sensitive display device is further provided, and the touch sensitive display device comprises the above-described touch screen. Since the touch screen has better performance and quality, the touch sensitive display device has stronger market competitiveness and better application prospects.

In summary, the present application provides a method for manufacturing a patterned silver nanowire film and a touch screen, wherein, a patterned surface modification layer 2 is formed on a substrate 1, and a silver nanowire solution is automatically scattered on the surface modification layer 2 and is gathered onto a portion of the substrate 1 that is not covered by the surface modification layer 2 by utilizing the property that the surface modification layer 2 repels the silver nanowire solution, thus to form a patterned silver nanowire film 3 after curing the silver nanowire solution. As compared with the existing laser etching technique, the method for manufacturing a patterned silver nanowire film provided in the present application is simple and rapid, and can further reduce equipment cost when applied to large-scale production. In addition, there is no waste of the silver nanowire solution in the production process, which improves the utilization rate of the silver nanowire material. Therefore, the present application provides a low-cost and high-efficiency method for manufacturing a patterned silver nanowire film. Moreover, the patterned silver nanowire film manufactured by the method for manufacturing a patterned silver nanowire film proposed by the present application avoids the laser etching technique, so there is no laser etching sintering trace produced on the substrate. Therefore, the touch screen manufactured by this method has better performance and quality, and the display panel and the touch sensitive display device manufactured by this method have stronger market competitiveness and better application prospects.

Apparently, for a person skilled in the art, various changes and modifications can be made to the present application without departing from the concept and scope of the present application. Accordingly, if these changes and modifications to the present application fall within the scope of the claims of the present application and their equivalents, the present application is intended to include these changes and modifications herein.

1. A method for manufacturing a patterned silver nanowire film, comprising:
forming a patterned surface modification layer on a substrate;
coating a silver nanowire solution on the substrate, the surface modification layer repeling the silver nanowire solution, the silver nanowire solution being automatically scattered on the surface modification layer and being gathered onto a portion of the substrate that is not covered by the surface modification layer; and
performing a baking process to cure the silver nanowire solution to form the patterned silver nanowire film.

2. The method for manufacturing a patterned silver nanowire film according to claim 1, wherein in the step of coating a silver nanowire solution on the substrate, the surface modification layer has hydrophobicity when the silver nanowire solution has an aqueous solvent.

3. The method for manufacturing a patterned silver nanowire film according to claim 2, wherein in the step of forming a patterned surface modification layer on a substrate, the surface modification layer is formed by a surface modifier, and the surface modifier includes one or more of a silane coupling agent, a linear alkyl type surface modifier, a branched alkyl type surface modifier, a rosin derivative surface modifier, a fluoroalkyl surface modifier, a polysiloxane based surface modifier.

4. The method for manufacturing a patterned silver nanowire film according to claim 1, wherein in the step of forming a patterned surface modification layer on a substrate, the surface modification layer has a first pattern, and the silver nanowire film has a second pattern, the first pattern and the second pattern are complementary and collectively cover the entire substrate.

5. The method for manufacturing a patterned silver nanowire film according to claim 4, wherein the surface modification layer is formed by the following steps:
providing a transfer plate;
coating a patterned surface modifier onto the transfer plate;
transferring the surface modifier from the transfer plate to the substrate by a transfer printing method; and
curing the surface modifier to form the surface modification layer.

6. The method for manufacturing a patterned silver nanowire film according to claim 5, wherein the surface modifier in the first pattern is formed on the transfer plate by a screen printing method.

7. The method for manufacturing a patterned silver nanowire film according to claim 1, wherein in the step of coating a silver nanowire solution on the substrate, the silver nanowire solution comprises a plurality of sliver nanowires which are distributed in a solvent of the silver nanowire solution.

8. The method for manufacturing a patterned silver nanowire film according to claim 1, wherein in the step of coating a silver nanowire solution on the substrate, the silver nanowire solution has a concentration of 0.01 mg/mL to 10 mg/mL.

9. The method for manufacturing a patterned silver nanowire film according claim 1, wherein in the step of coating a silver nanowire solution on the substrate, the solvent of the silver nanowire solution is ethylene glycol or isopropanol.

10. A method for manufacturing a touch screen, wherein, the touch screen comprises a patterned silver nanowire film which is manufactured by the method for manufacturing a patterned silver nanowire film according to claim 1.

11. A touch screen, comprising:
a substrate;
a patterned surface modification layer formed on the substrate; and
a patterned silver nanowire film formed on a portion of the substrate that is not covered by the surface modification layer.

12. The touch screen according to claim 11, wherein the surface modification layer has a first pattern, and the silver nanowire film has a second pattern, the first pattern and the second pattern are complementary and collectively cover the entire substrate.

13. The touch screen according to claim 12, wherein the patterned silver nanowire film is manufactured by the method for manufacturing a patterned silver nanowire film according to claim 1.
